(19) United States
(12) Patent Application Publication
(10) Pub. No.: US 2026/0230061 A1
(43) Pub. Date: Aug. 6, 2026

(54) ACOUSTIC WAVE FILTER AND COMMUNICATION APPARATUS

(71) Applicant: KYOCERA CORPORATION, Kyoto (JP)

(72) Inventor: Tomio KANAZAWA, Kyoto (JP)

(73) Assignee: KYOCERA CORPORATION, Kyoto (JP)

(21) Appl. No.: 19/148,379

(22) PCT Filed: Jan. 10, 2024
(86) PCT No.: PCT/JP2024/000233

§ 371 Date: Jul. 16, 2025

(30) Foreign Application Priority Data
Jan. 23, 2023 (JP) 2023-008264

(51) Int. Cl. H03H 9/58; H03H 9/25; H03H 9/54

(52) U.S. Cl. CPC H03H 9/583; H03H 9/25; H03H 9/542

(57) ABSTRACT

To improve the performance of an acoustic wave filter. An acoustic wave element in the acoustic wave filter includes a piezoelectric-body layer, an IDT electrode located on the piezoelectric-body layer, a low-acoustic-velocity film having an acoustic velocity lower than that of the piezoelectric-body layer, and a support substrate having an acoustic velocity higher than that of the piezoelectric-body layer. When a wavelength of an acoustic wave excited by the IDT electrode is defined by λ, a thickness of the piezoelectric-body layer is equal to or less than λ. The acoustic wave filter includes a transmission filter including a first acoustic wave element group among the plurality of acoustic wave elements, and a reception filter including a second acoustic wave element group different from the first acoustic wave element group among the plurality of acoustic wave elements. A passband of the transmission filter is located on a higher frequency side than a passband of the reception filter, and a width of the passband of the transmission filter is wider than a width of the passband of the reception filter.

### TECHNICAL FIELD

An aspect of the present disclosure relates to an acoustic wave filter.

### BACKGROUND OF INVENTION

Patent Document 1 below discloses a configuration example of a multiplexer as an example of acoustic wave filters.

### Citation List

### Patent Literature

Patent Document 1: JP 2021-5742 A

### SUMMARY

An acoustic wave filter according to an aspect of the present disclosure is an acoustic wave filter including a plurality of acoustic wave elements, in which each of the acoustic wave element includes: a piezoelectric-body layer; an IDT electrode located on the piezoelectric-body layer; a low-acoustic-velocity film having an acoustic velocity lower than the acoustic velocity of the piezoelectric-body layer; and a support substrate having an acoustic velocity higher than the acoustic velocity of the piezoelectric-body layer, when a wavelength of an acoustic wave excited by the IDT electrode is denoted by λ, a thickness of the piezoelectric-body layer is equal to or less than λ, the acoustic wave filter includes: a transmission filter including a first acoustic wave element group among the plurality of acoustic wave elements; and a reception filter including a second acoustic wave element group different from the first acoustic wave element group among the plurality of acoustic wave elements, a passband of the transmission filter is located on a higher frequency side than a passband of the reception filter, and a width of the passband of the transmission filter is wider than a width of the passband of the reception filter.

An acoustic wave filter according to an aspect of the present disclosure is an acoustic wave filter including a plurality of acoustic wave elements, in which each of the acoustic wave elements includes: a piezoelectric-body layer; an IDT electrode located on the piezoelectric-body layer; a low-acoustic-velocity film having an acoustic velocity lower than the acoustic velocity of the piezoelectric-body layer; and a support substrate having an acoustic velocity higher than the acoustic velocity of the piezoelectric-body layer, when a wavelength of an acoustic wave excited by the IDT electrode is denoted by λ, a thickness of the piezoelectric-body layer is equal to or less than λ, the acoustic wave filter includes: a transmission filter including a first acoustic wave element group among the plurality of acoustic wave elements; and a reception filter including a second acoustic wave element group different from the first acoustic wave element group among the plurality of acoustic wave elements, a passband of the transmission filter is spaced apart from a passband of the reception filter by 50 MHz or more, and a width of the passband of the transmission filter is wider than a width of the passband of the reception filter.

### BRIEF DESCRIPTION OF THE DRAWINGS

FIG. 1 illustrates a configuration example of an acoustic wave element in an acoustic wave filter according to a first embodiment.

FIG. 2 illustrates a configuration example of the acoustic wave filter according to the first embodiment.

FIG. 3 schematically illustrates examples of frequency characteristics of acoustic wave filters in a comparative example and an example.

FIG. 4 schematically illustrates examples of frequency characteristics of one acoustic wave element in the comparative example and the example.

FIG. 5 illustrates an example of frequency characteristics of the acoustic wave filters in a first example and a second example.

FIG. 6 illustrates examples of power consumption characteristics of series resonators in the first example and the second example.

FIG. 7 exemplifies a schematic configuration of a communication apparatus in a third embodiment.

### DESCRIPTION OF EMBODIMENTS

### First Embodiment

An acoustic wave filter 100 of a first embodiment is described below. For convenience of description, a component having the same function as that described in the first embodiment will be denoted by the same reference sign in each of subsequent embodiments, and a description thereof will not be repeated. For simplicity, descriptions of known technical matters will be omitted as appropriate. Each component, material, and numerical value described herein is merely an example, unless otherwise contradicted. Therefore, for example, as long as there is no particular contradiction, the positional relationship and the connection relationship of the components are not limited to the examples in the drawings. The figures are not necessarily drawn to scale.

### Configuration Example of Acoustic Wave Element

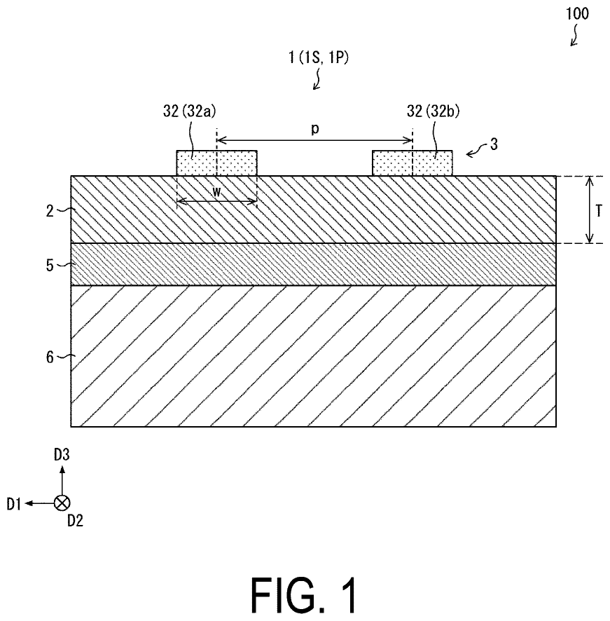

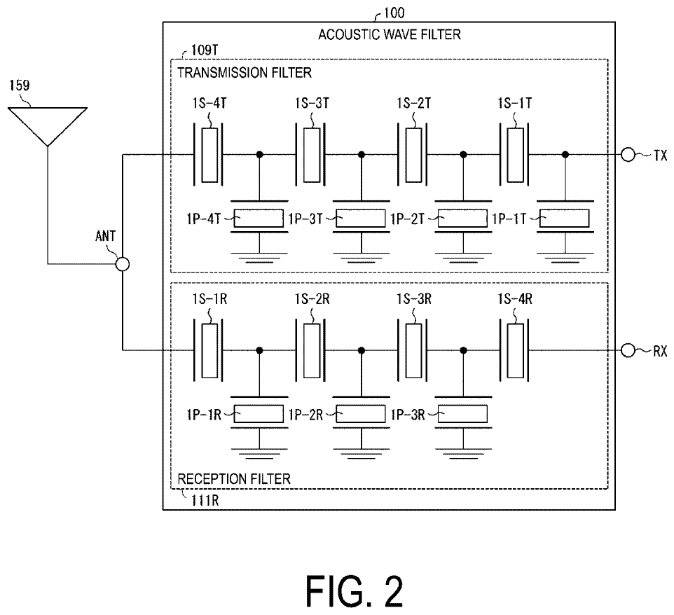

FIG. 1 illustrates a configuration example of an acoustic wave element 1 in the acoustic wave filter 100. The acoustic wave element 1 is also referred to as an acoustic wave resonator. FIG. 1 schematically illustrates a laminated structure of the acoustic wave element 1. FIG. 1 illustrates a portion of one acoustic wave element 1. As illustrated in FIG. 2 described later, the acoustic wave filter 100 may include one or more acoustic wave elements 1. Specifically, as described below, the acoustic wave filter 100 may include a series resonator 1S and a parallel resonator 1P as the acoustic wave element 1.

In the present specification, for convenience of description, an orthogonal coordinates system (D1/D2/D3 coordinates system) illustrated in FIG. 1 is introduced. In the example of the first embodiment, a D1 direction is a propagation direction of an acoustic wave propagating in a piezoelectric-body layer 2 of the acoustic wave element 1. As illustrated in FIG. 1, a plurality of electrode fingers 32 of each of the acoustic wave elements 1 may be arranged in the D1 direction. A D2 direction is an example of a direction intersecting the D1 direction. The electrode fingers 32 may extend in the D2 direction. A D3 direction is a thickness direction of each portion of the acoustic wave element 1. In the present specification, the positive direction of the D3 direction will be described as an upward direction. Thus, the negative direction of the D3 direction is a downward direction.

The acoustic wave element 1 may include (i) the piezoelectric-body layer 2, (ii) an interdigital transducer (IDT) electrode 3 located on the piezoelectric-body layer 2, (iii) a low-acoustic-velocity film 5, and (iv) a support substrate 6. The support substrate 6, the low-acoustic-velocity film 5, and the piezoelectric-body layer 2 may be common to the plurality of acoustic wave elements 1. On the other hand, each of the plurality of acoustic wave elements 1 may include the individual IDT electrode 3. The IDT electrode 3 is also referred to as an excitation electrode.

The support substrate 6 supports each part of the acoustic wave element 1. Thus, the support substrate 6 may be located below the low-acoustic-velocity film 5. The support substrate 6 may have an acoustic velocity higher than that of the piezoelectric-body layer 2. Therefore, for example, the support substrate 6 may contain Si as a material.

The piezoelectric-body layer 2 may be made of a piezoelectric monocrystal material. The piezoelectric-body layer 2 may contain lithium tantalate (LiTaO₃: also referred to as LT) as a material. The cut angle of LT may be set as appropriate. As an example, the piezoelectric-body layer 2 may contain Y-cut X-propagation LT having a cut angle of 40° or less as a material (see a first example described later). As another example, the piezoelectric-body layer 2 may contain Y-cut X-propagation LT having a cut angle of 25°±3° as a material (see a second example described later).

An X-axis and a Y-axis each are crystal orientation axes of the piezoelectric-body layer 2. For example, “Y-cut X-propagation LT having a cut angle of 40°” means “LT cut by a plane having an axis as a normal line rotated by 40° from the Y-axis with the X-axis as a central axis when an X-axis direction is the propagation direction of the acoustic wave”. The X-axis and the Y-axis may be associated with the D1 to D3 directions. For example, the direction of the X-axis may coincide with the D1 direction. However, the X-axis and the Y-axis may not be associated with the D1 to D3 directions.

The IDT electrode 3 may include a first bus bar and a second bus bar (not illustrated) facing each other in the D2 direction. The IDT electrode 3 may include (i) a plurality of first electrode fingers 32a connected to the first bus bar and (ii) a plurality of second electrode fingers 32b connected to the second bus bar. In the present specification, the first electrode fingers 32a and the second electrode fingers 32b may collectively referred to as the electrode fingers 32.

The first electrode fingers 32a may extend from the first bus bar side to the second bus bar side in the D2 direction. The second electrode fingers 32b may extend from the second bus bar side to the first bus bar side in the D2 direction. Thus, the second electrode fingers 32b and the first electrode fingers 32a may be interdigitated with each other in the D2 direction.

Each of the plurality of electrode fingers 32 may be alternately and repeatedly located on the piezoelectric-body layer 2 at substantially regular intervals in the D1 direction. In the present specification, the pitch of the electrode fingers 32 is denoted by p. p is also referred to as an electrode finger pitch of the IDT electrode 3. For example, p may be a pitch (repetition interval) in the D1 direction between the centers of two adjacent electrode fingers 32.

In the present specification, the wavelength of the acoustic wave excited by the IDT electrode 3 is denoted by λ. As an example, p may be set equal to a half value (λ/2) of λ. In this case, λ may be defined as twice the length of p. In the first embodiment, a case where λ=2p is exemplified.

In the present specification, the length of the electrode finger 32 in the D1 direction is referred to as a width w of the electrode finger 32. The w may be set appropriately according to the electric characteristics required for the acoustic wave element 1, for example. As an example, the w may be set according to p. In the present specification, a ratio of w to p (w/p) is referred to as Duty (duty) of the electrode fingers 32.

As an example, by changing Duty, the frequency characteristics of the acoustic wave element 1 can be controlled. As another example, the frequency characteristics of the acoustic wave element 1 can also be controlled by changing w or p while maintaining Duty constant. As described above, the frequency characteristics of each of the plurality of acoustic wave elements 1 can be controlled by changing the design of the IDT electrode 3 in each of the plurality of acoustic wave elements 1. As described above, the frequency characteristics of the acoustic wave filter 100 can be controlled by changing the design of the IDT electrode 3.

In the present specification, the thickness of the piezoelectric-body layer 2 is denoted by T. In the first embodiment, a case in which the piezoelectric-body layer 2 is sufficiently thin, that is, a case in which T is sufficiently small is exemplified. As an example, T may be equal to or less than λ. In this case, the IDT electrode 3 may excite a plate wave (Lamb wave) as an acoustic wave. As an example, the IDT electrode 3 may excite an A1 Lamb wave as a plate wave.

The low-acoustic-velocity film 5 is an example of an interposed layer located between the piezoelectric-body layer 2 and the support substrate 6. The low-acoustic-velocity film 5 may be located below the piezoelectric-body layer 2. The low-acoustic-velocity film 5 may have an acoustic velocity lower than that of the piezoelectric-body layer 2. Therefore, for example, the low-acoustic-velocity film 5 may contain SiO₂ as a material.

The acoustic wave element 1 may further include an interposed layer different from the low-acoustic-velocity film 5. For example, the acoustic wave element 1 may include an acoustic wave reflective film between the piezoelectric-body layer 2 and the support substrate 6 as the different interposed layer. The acoustic wave reflective film may be a multilayer reflective film in which (i) a low acoustic impedance layer having an acoustic impedance lower than that of the piezoelectric-body layer 2 and (ii) a high acoustic impedance layer having an acoustic impedance higher than that of the piezoelectric-body layer 2 are alternately laminated.

The multilayer reflective film may be a laminated unit composed of one low acoustic impedance layer and one high acoustic impedance layer that are laminated together. The acoustic wave element 1 may include, for example, four laminated units. The low acoustic impedance layer may contain SiO₂ as a material. The high acoustic impedance layer may contain HfO₂ as a material.

### Configuration Example of Acoustic Wave Filter

FIG. 2 illustrates a configuration example of the acoustic wave filter 100. In the first embodiment, a case in which the acoustic wave filter 100 is a multiplexer (demultiplexer) is exemplified. In the first embodiment, for the sake of simplicity of description, the acoustic wave filter 100 as a duplexer is exemplified.

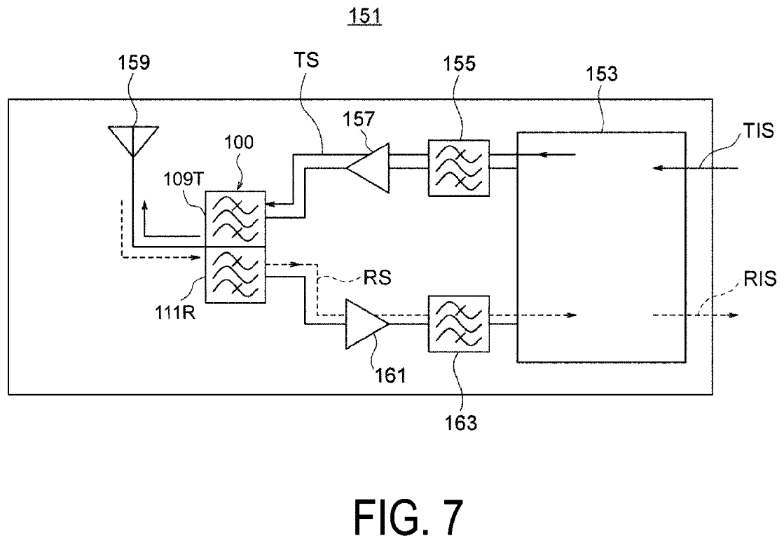

The acoustic wave filter 100 may include a transmission filter 109T and a reception filter 111R. In FIG. 2, the transmission filter 109T and the reception filter 111R are illustrated as a ladder-type filter. The transmission filter 109T and the reception filter 111R may be connected to an antenna 159 via an antenna terminal ANT (see also FIG. 7 described later).

Each of the transmission filter 109T and the reception filter 111R may include the plurality of acoustic wave elements 1. In the present specification, for convenience of description, among the plurality of acoustic wave elements 1, the acoustic wave elements belonging to the transmission filter 109T are denoted by reference sign T, and the acoustic wave elements belonging to the reception filter 111R are denoted by reference sign R.

In the present specification, a group of the acoustic wave elements 1 belonging to the transmission filter 109T is referred to as a first acoustic wave element group. On the other hand, a group of the acoustic wave elements 1 belonging to the reception filter 111R is referred to as a second acoustic wave element group. The second acoustic wave element group is different from the first acoustic wave element group. By making the second acoustic wave element group different from the first acoustic wave element group, a transmission band and a reception band described later can be made different from each other. By not including the common acoustic wave element 1 in the first acoustic wave element group and the second acoustic wave element group, the transmission band and the reception band are easily spaced apart from each other.

The transmission filter 109T may include four series resonators 1S located on series arms of the transmission filter 109T. In the example of FIG. 2, the four series resonators 1S in the transmission filter 109T are referred to as series resonators 1S-1T to 1S-4T, respectively. The series resonators 1S-1T to 1S-4T may be collectively referred to as series resonators 1S-T.

The series arms of the transmission filter 109T may be connected to a transmission terminal TX and the antenna terminal ANT. In the example of FIG. 2, the series resonator 1S-1T is a series resonator closest to the transmission terminal TX. On the other hand, the series resonator 1S-4T is a series resonator closest to the antenna terminal ANT.

The transmission filter 109T may include four parallel resonators 1P located on parallel arms of the transmission filter 109T. In the example of FIG. 2, the four parallel resonators 1P in the transmission filter 109T are referred to as parallel resonators 1P-1T to 1P-4T, respectively. The parallel resonators 1P-1T to 1P-4T may be collectively referred to as parallel resonators 1P-T. The parallel resonators 1P-T may be grounded.

In the example of FIG. 2, the parallel resonator 1P-1T is a parallel resonator closest to the transmission terminal TX. The parallel resonator 1P-1T may be located on the parallel arm extending from between the series resonator 1S-1T and the transmission terminal TX. On the other hand, the parallel resonator 1P-4T is a parallel resonator closest to the antenna terminal ANT. The parallel resonator 1P-4T may be located on the parallel arm extending from between the series resonator 1S-4T and the series resonator 1S-3T.

The reception filter 111R may include four series resonators 1S located on series arms of the reception filter 111R. In the example of FIG. 2, the four series resonators 1S in the reception filter 111R are referred to as series resonators 1S-1R to 1S-4R, respectively. The series resonators 1S-1R to 1S-4R in the reception filter 111R may be collectively referred to as series resonators 1S-R.

The series arms of the reception filter 111R may be connected to a reception terminal RX and the antenna terminal ANT. In the example of FIG. 2, the series resonator 1S-1R is a series resonator closest to the antenna terminal ANT. On the other hand, the series resonator 1S-4R is a series resonator closest to the reception terminal RX.

The reception filter 111R may include three parallel resonators 1P located on parallel arms of the reception filter 111R. In the example of FIG. 2, the three parallel resonators 1P in the reception filter 111R are referred to as parallel resonators 1P-1R to 1P-3R, respectively. The parallel resonators 1P-1R to 1P-3R may be collectively referred to as parallel resonators 1P-R. The parallel resonators 1P-R may be grounded.

In the example of FIG. 2, the parallel resonator 1P-1R is a parallel resonator closest to the antenna terminal ANT. The parallel resonator 1P-1R may be located on the parallel arm extending from between the series resonator 1S-1R and the series resonator 1S-2R. On the other hand, the parallel resonator 1P-3R is a parallel resonator closest to the reception terminal RX. The parallel resonator 1P-3R may be located on the parallel arm extending from between the series resonator 1S-3R and the series resonator 1S-4R.

The transmission filter 109T may include the series resonators 1S-T and the parallel resonators 1P-T as the first acoustic wave element group. On the other hand, the reception filter 111R may include the series resonators 1S-R and the parallel resonators 1P-R as the second acoustic wave element group.

### Schematic Example of Frequency Characteristics of Acoustic Wave Filter

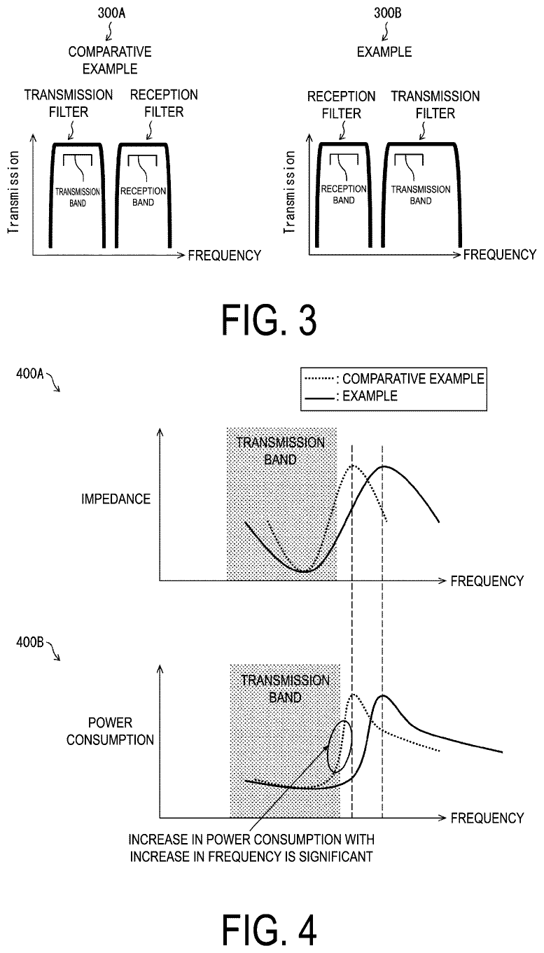

FIG. 3 schematically illustrates examples of frequency characteristics (specifically, attenuation characteristics) of an acoustic wave filter according to a comparative example (for example, a known acoustic wave filter) and an acoustic wave filter according to an example (for example, the acoustic wave filter 100). In FIG. 3, a reference sign 300A indicates an example of the attenuation characteristics in the comparative example, and a reference sign 300B indicates an example of the attenuation characteristics in the example.

In the graph of FIG. 3, a horizontal axis represents the frequency (unit: Hz), and a vertical axis (Transmission) represents an attenuation amount (unit: dB). The attenuation amount can be read as insertion loss. In the following description, the passband of the transmission filter is referred to as a transmission band, and the passband of the reception filter is referred to as a reception band.

The transmission band and the passband depicted by the objects in square brackets in FIG. 3 respectively indicate the transmission band and the reception band specified by the standard. In the present specification, the transmission band specified by the standard is referred to as a specified transmission band. The reception band specified by the standard is referred to as a specified reception band.

The actual transmission band of the transmission filter may be defined as, for example, a frequency band from a low-frequency-side cutoff frequency to a high-frequency-side cutoff frequency in the transmission filter. As is apparent to those skilled in the art, in the attenuation characteristics of the frequency filter, a −3 dB attenuation point (point at which the attenuation amount is −3 dB) is present on each of the low-frequency side and the high-frequency side with respect to the peak frequency indicating the frequency at the minimum attenuation amount.

The high-frequency-side cutoff frequency (referred to as an fcut1_T for the sake of simplicity) of the transmission filter is a frequency at a −3 dB attenuation point on the high-frequency side of the peak frequency in the transmission filter. The low-frequency-side cutoff frequency (referred to as an fcut2_T for the sake of simplicity) of the transmission filter is a frequency at a −3 dB attenuation point on the low-frequency side of the peak frequency in the transmission filter.

Therefore, the transmission band in the present specification may be defined as a frequency band from the fcut2_T to the fcut1_T. As described above, the transmission bandwidth (the width of the transmission band) can be defined by the width from the −3 dB attenuation point on the low-frequency side to the −3 dB attenuation point on the high-frequency side in the attenuation characteristics of the transmission filter. In this case, the fcut2_T is a frequency at the end portion of the transmission band on the low-frequency side, and the fcut1_T is a frequency at the end portion of the transmission band on the high-frequency side.

The actual reception band of the reception filter may be defined as, for example, a frequency band from a low-frequency-side cutoff frequency to a high-frequency-side cutoff frequency in the reception filter. The high-frequency-side cutoff frequency (referred to as an fcut1 R for the sake of simplicity) of the reception filter is a frequency at a −3 dB attenuation point on the high-frequency side of the peak frequency in the reception filter. The low-frequency-side cutoff frequency (referred to as an fcut2_R for the sake of simplicity) of the reception filter is a frequency at a −3 dB attenuation point on the low-frequency side of the peak frequency in the reception filter.

Therefore, the reception band in the present specification may be defined as a frequency band from the fcut2_R to the fcut1_R. As described above, the reception bandwidth (the width of the reception band) can be defined by the width from the −3 dB attenuation point on the low-frequency side to the −3 dB attenuation point on the high-frequency side in the attenuation characteristics of the reception filter. In this case, the fcut2_R is a frequency at the end of the reception band on the low-frequency side, and the fcut1_R is a frequency at the end portion of the reception band on the high-frequency side.

Unless otherwise contradicted, the transmission band in the description of the present specification may be understood as referring to a frequency band defined by the-3 dB attenuation point in the attenuation characteristics of the transmission filter. The reception band in the description of the present specification may be understood as referring to a frequency band defined by the −3 dB attenuation point in the attenuation characteristics of the reception filter.

The transmission filters in the comparative example and the example are both designed, thus the transmission band includes the specified transmission band. The reception filters in the comparative example and the example are both designed, thus the reception band includes the specified reception band. As is apparent to those skilled in the art, the transmission band and the reception band may vary depending on the standard to which the acoustic wave filter conforms.

As indicated by the reference sign 300A in FIG. 3, in the known acoustic wave filter, the transmission band may be located on the lower frequency side than the reception band due to, for example, a requirement of the standard (for example, see Patent Document 1). Therefore, in the comparative example, the frequency characteristics of each of the transmission filter and the reception filter are set, thus the transmission band is located on the lower frequency side than the reception band.

In contrast, as indicated by the reference sign 300B in FIG. 3, in the example, the transmission band is located on the lower frequency side than the reception band. Therefore, in the example, the frequency characteristics of each of the transmission filter and the reception filter are set, thus the transmission band is located on the higher frequency side than the reception band.

### Schematic Example of Frequency Characteristics of Acoustic Wave Element

FIG. 4 schematically illustrates examples of frequency characteristics of one acoustic wave element in the comparative example and the example. In FIG. 4, a reference sign 400A indicates an example of the impedance characteristics of the acoustic wave element, and a reference sign 400B indicates an example of the power consumption characteristics of the acoustic wave element.

In the example of FIG. 4, the transmission band in the comparative example and the transmission band in the example are illustrated at the same position for simplicity of the drawing. However, it should be noted that, in practice, as illustrated in FIG. 3, the transmission band is located on the lower frequency side than the reception band in the comparative example, and the transmission band is located on the higher frequency side than the reception band in the example.

The horizontal axis in each of the reference sign 400A and the reference sign 400B in FIG. 4 indicates the frequency. The vertical axis in the reference sign 400A indicates the magnitude (absolute values) of the impedance of the acoustic wave element. In the following description, unless otherwise contradicted, the magnitude of the impedance is simply abbreviated as “impedance”. The vertical axis in the reference sign 400B indicates the power consumption of the acoustic wave element.

In the present specification, the resonant frequency (referred to as fr for convenience) of the acoustic wave element is defined as a frequency at which the impedance is minimized. In contrast, the anti-resonant frequency (referred to as fa for convenience) of the acoustic wave element is defined as a frequency at which the impedance is maximized.

In general, the power consumption increases with an increase in impedance. As illustrated in FIG. 4, the power consumption is minimized near fr. Ideally, the power consumption is minimized at fr. On the other hand, the power consumption is maximized near fa. Ideally, the power consumption is maximized at fa.

In the example of FIG. 4, fr<fa. In the example of FIG. 4, fr in the comparative example and fr in the example are assumed to be equal to each other. In the example of FIG. 4, fr is assumed to belong to the transmission band. In the example of FIG. 4, the maximum values of the impedances in the comparative example and the example are assumed to be equal to each other. Therefore, in the example of FIG. 4, the maximum values of the power consumption in the comparative example and the example are also assumed to be equal to each other.

However, in the example of FIG. 4, fa in the comparative example and fa in the example are different from each other. Specifically, in the example of FIG. 4, fa in the example is higher than fa in the comparative example. The bandwidth of the acoustic wave element may be defined as Δf=|fa-fr|. Therefore, in the example of FIG. 4, Δf in the example is larger than Δf in the comparative example.

In general, the temperature of the acoustic wave element increases as the power consumption of the acoustic wave element increases. The shoulder on the low-frequency side of the transmission band in the acoustic wave filter may shift to the low-frequency side with an increase in the temperature of the acoustic wave element. In order to compensate for the shift of the shoulder on the low-frequency side of the transmission band to the low-frequency side, for example, it is conceivable to design the acoustic wave filter whose shoulder on the high-frequency side of the transmission band shifts to the high-frequency side.

However, in a general multiplexer, it is necessary to cause the transmission band to be spaced apart from the reception band. Therefore, in the comparative example in which the transmission band is located on the lower frequency side than the reception band, it may be difficult to shift the shoulder on the high-frequency side of the transmission band to the high-frequency side for the convenience of causing the transmission band and the reception band to be spaced apart from each other.

Based on this, in the comparative example in FIG. 3 described above, a case in which the transmission bandwidth is the same as the reception bandwidth is illustrated. Therefore, in the comparative example, as illustrated in FIG. 4, an increase in power consumption due to an increase in frequency may be significant near the end portion on the high-frequency side of the transmission band.

On the other hand, in the example, since the transmission band is located on the higher frequency side than the reception band, even when the shoulder on the high-frequency side of the transmission band is shifted to the high-frequency side, the transmission band and the reception band can be maintained in a spaced-apart state.

Based on this, in the example in FIG. 3 described above, a case in which the transmission bandwidth is wider than the reception bandwidth is illustrated. As an example, in the acoustic wave filter according to an aspect of the present disclosure, the transmission bandwidth may be wider than the reception bandwidth by 2 MHz or more. As another example, the transmission bandwidth may be wider than the reception bandwidth by 4 MHz or more.

As described above, in the example, the degree of freedom of frequency selection on the high-frequency side of the transmission band is higher than that in the comparative example. Therefore, in the example, fa is easily set to be higher than that in the comparative example. In other words, in the example, Δf is easily set to be larger than that in the comparative example. As illustrated in FIG. 4, the power consumption increases substantially monotonically with an increase in frequency in a range from the end portion on the high-frequency side of the transmission band to fa. However, in the example, since Δf can be set to be larger than that in the comparative example, the degree of increase in power consumption with an increase in frequency can be made gentler than that in the comparative example.

As a result, in the example, the variation in power consumption in each acoustic wave element in the frequency filter can be reduced as compared with the comparative example. Therefore, according to the example, a frequency filter having higher power durability than the comparative example can be achieved. Therefore, according to the example, for example, a frequency filter having excellent mass productivity can be achieved.

As described above, the acoustic wave filter 100 can achieve, for example, a wider transmission band and improved power durability. As described above, the acoustic wave filter 100 can improve the performance of the acoustic wave filter as compared with the related art.

### Further Study on Frequency Characteristics of Acoustic Wave Filter According to Example

The inventor of the present application further studied the examples through simulation. Specifically, the inventor performed simulation for each of a first example and a second example described below.

In the simulation in the first example, the inventor set the design conditions of the acoustic wave element 1 as follows.
Piezoelectric-body layer: LT (thickness T=0.35 λ)
Low-acoustic-velocity film: SiO₂ (thickness: 0.1 λ)
Support substrate: Si (thickness: 40 λ)
Thickness of IDT electrode: 0.09 λ
Cut angle of LT: 40°

On the other hand, the inventor set the design conditions of the acoustic wave element 1 in the second example by changing the cut angle of LT to 26° in the design conditions of the acoustic wave element 1 in the first example. The design conditions of the acoustic wave element 1 except for the cut angle of LT are the same in the first example and the second example.

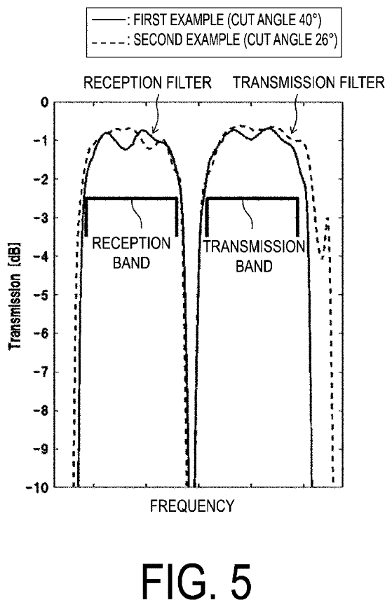

The inventor derived the frequency characteristics of the acoustic wave filter in each of the first and second examples by the simulation. FIG. 5 illustrates an example of frequency characteristics of the acoustic wave filters in the first and second examples, which are derived by the inventor. FIG. 5 corresponds to the example of the reference sign 300B in FIG. 3 described above. As illustrated in FIG. 5, in the second example, the transmission bandwidth can be further widened to the high-frequency side as compared with the first example. Therefore, according to the second example, the power consumption on the high-frequency side can be further reduced as compared with the first example.

As can be understood from the above description, the performance of the acoustic wave filter can be improved as compared with the related art by setting the cut angle of LT to 40° or less. In addition, the performance of the acoustic wave filter is able to be further improved by setting the cut angle of LT to 25°±3°.

Further Study on Power Consumption Characteristics of Series Resonators According to Examples

The inventor derived the frequency characteristics of the power consumption of the acoustic wave element in each of the first and second examples by simulation. Specifically, the inventor derived the frequency characteristics of the power consumption of the series resonators 1S-1T to 1S-4 for each of the first and second examples.

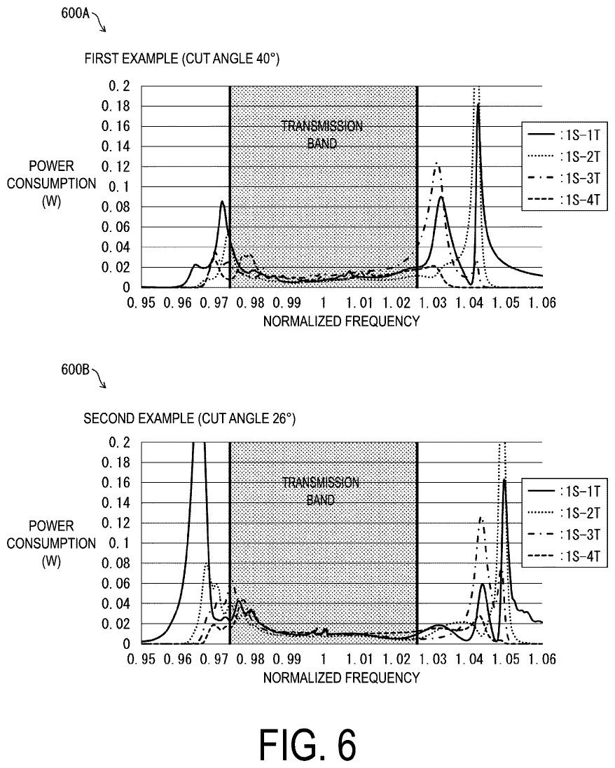

FIG. 6 illustrates examples of power consumption characteristics of the series resonators in the first example and the second example, which are derived by the inventor. In FIG. 6, a reference numeral 600A indicates an example of the power consumption characteristics in the first example, and a reference numeral 600B indicates an example of the power consumption characteristics in the second example.

The transmission band illustrated in FIG. 6 is a specified transmission band. Thus, the transmission band described in the example of FIG. 6 refers to the specified transmission band. In the graph of FIG. 6, the horizontal axis indicates a normalized frequency scale. The normalized frequency is an amount obtained by dividing the frequency by the center frequency of the transmission band. Therefore, in the example of FIG. 6, the frequency corresponding to the value “1” on the horizontal axis is equal to the center frequency of the transmission band.

In both of the first and second examples, the series resonators 1S-1T to 1S-4 have peaks of power consumption on the low-frequency side and the high-frequency side of the transmission band. In the example of FIG. 6, attention is paid to the peak of power consumption on the high-frequency side with respect to the transmission band. In the present specification, the frequency at which the power consumption takes the peak value is referred to as a peak frequency of the power consumption (power consumption peak frequency).

As illustrated in FIG. 6, in both of the first and second examples, the power consumption peak frequency of at least one of the series resonators 1S-1T to 1S-4 is located in a range of 1.035 or more on the horizontal axis (for example, see the graph of the series resonator 1S-2T in FIG. 6).

As described above, in the acoustic wave filter according to an aspect of the present disclosure, the power consumption peak frequency of the series resonator may be equal to or higher than 1.035 times the normalized frequency. In this case, the power consumption peak frequency of the series resonator can be sufficiently spaced apart from the transmission band on the high-frequency side. Accordingly, the power consumption of the series resonator during the operation of the acoustic wave filter can be effectively reduced.

As can be understood from the above description, according to the second example, Δf can be set to be large as compared with the first example. As described above, in the acoustic wave filter according to the aspect of the present disclosure, a large Δf can be obtained by appropriately setting the cut angle of LT. Therefore, as illustrated in FIG. 6, according to the second example, the power consumption peak frequency of the series resonator can be increased as compared with the first example. As a result, according to the second example, the power consumption can be reduced effectively as compared with the first example.

### Second Embodiment

The first embodiment has exemplified the case in which the transmission band in the acoustic wave filter according to an aspect of the present disclosure is located on the higher frequency side than the reception band. However, the transmission band in the acoustic wave filter according to the aspect of the present disclosure is not necessarily located on the higher frequency side than the reception band. This is because, for example, when the transmission band and the reception band are sufficiently spaced apart from each other, there is room for the transmission bandwidth to be wider than the reception bandwidth even when the transmission band is located on the lower frequency side than the reception band.

As an example, in an acoustic wave filter according to an aspect of the present disclosure, the transmission band may be spaced apart from the reception band by 50 MHz or more. As another example, the transmission band may be spaced apart from the reception band by 300 MHz or more.

### Third Embodiment

FIG. 7 exemplifies a schematic configuration of a communication apparatus 151 according to a third embodiment. The communication apparatus 151 performs wireless communication using radio waves. The communication apparatus 151 may include an acoustic wave filter (for example, the acoustic wave filter 100) according to an aspect of the present disclosure.

In the communication apparatus 151, a radio frequency-integrated circuit (RF-IC) 153 may convert, into a transmission signal TS, a transmission information signal TIS including information to be transmitted, by modulating TIS and increasing the frequency of TIS (converting TIS to a high-frequency signal having a frequency of a carrier wave). A band-pass filter 155 may remove, from the TS, unnecessary components other than a transmission passband. Subsequently, the TS from which unnecessary components have been removed may be amplified by an amplifier 157 and sent to the transmission filter 109T.

The transmission filter 109T may remove, from the transmission signal TS input via the transmission terminal TX (not illustrated in FIG. 7), unnecessary components other than the transmission passband. The transmission filter 109T may output the TS from which unnecessary components have been removed, to the antenna 159 via an antenna terminal ANT (not illustrated in FIG. 7). The antenna 159 may convert the TS, which is an electrical signal input to the antenna 159, into a radio wave as a radio signal, and transmit the radio wave to the outside of the communication apparatus 151.

The antenna 159 may convert a radio wave received from the outside into a reception signal RS, which is an electrical signal. The antenna 159 may input the RS to the reception filter 111R via the antenna terminal ANT. The reception filter 111R may remove, from the input RS, unnecessary components other than a reception passband. The reception filter 111R may output the reception signal RS from which unnecessary components have been removed, to an amplifier 161 via the reception terminal RX (not illustrated in FIG. 7). The amplifier 161 may amplify the output RS. A band-pass filter 163 may remove, from the amplified RS, unnecessary components other than a reception passband. The RF-IC 153 may convert, into a reception information signal RIS, the RS from which unnecessary components have been removed, by decreasing the frequency of the RS and demodulating the RS.

The TIS and RIS may be low-frequency signals (baseband signals) including appropriate information. For example, the TIS and RIS may be analog audio signals or digitized audio signals. The passband of the radio signal may be appropriately set or may conform to various known standards.

### Conclusion

An acoustic wave filter according to a first aspect of the present disclosure is an acoustic wave filter including a plurality of acoustic wave elements, in which each of the acoustic wave elements includes: a piezoelectric-body layer; an IDT electrode located on the piezoelectric-body layer; a low-acoustic-velocity film having an acoustic velocity lower than the acoustic velocity of the piezoelectric-body layer; and a support substrate having an acoustic velocity higher than the acoustic velocity of the piezoelectric-body layer, when a wavelength of an acoustic wave excited by the IDT electrode is denoted by λ, a thickness of the piezoelectric-body layer is equal to or less than λ, the acoustic wave filter includes: a transmission filter including a first acoustic wave element group among the plurality of acoustic wave elements; and a reception filter including a second acoustic wave element group different from the first acoustic wave element group among the plurality of acoustic wave elements, a passband of the transmission filter is located on a higher frequency side than a passband of the reception filter, and a width of the passband of the transmission filter is wider than a width of the passband of the reception filter.

An acoustic wave filter according to a second aspect of the present disclosure is an acoustic wave filter including a plurality of acoustic wave elements, in which each of the acoustic wave elements includes: a piezoelectric-body layer; an IDT electrode located on the piezoelectric-body layer; a low-acoustic-velocity film having an acoustic velocity lower than the acoustic velocity of the piezoelectric-body layer, and a support substrate having an acoustic velocity higher than the acoustic velocity of the piezoelectric-body layer, when a wavelength of an acoustic wave excited by the IDT electrode is denoted by λ, a thickness of the piezoelectric-body layer is equal to or less than λ, the acoustic wave filter includes: a transmission filter including a first acoustic wave element group among the plurality of acoustic wave elements; and a reception filter including a second acoustic wave element group different from the first acoustic wave element group among the plurality of acoustic wave elements, a passband of the transmission filter is spaced apart from a passband of the reception filter by 50 MHz or more, and a width of the passband of the transmission filter is wider than a width of the passband of the reception filter.

In an acoustic wave filter according to a third aspect of the present disclosure, in the second aspect, the passband of the transmission filter may be spaced apart from the passband of the reception filter by 300 MHz or more.

In an acoustic wave filter according to a fourth aspect of the present disclosure, in any one of the first to third aspects, when a width of the passband of the transmission filter is defined by a width from a −3 dB attenuation point on a low-frequency side to a −3 dB attenuation point on a high-frequency side in attenuation characteristics of the transmission filter, and a width of the passband of the reception filter is defined by a width from a −3 dB attenuation point on a low-frequency side to a −3 dB attenuation point on a high-frequency side in attenuation characteristics of the reception filter, a width of the passband of the transmission filter may be wider than a width of the passband of the reception filter by 2 MHz or more.

In an acoustic wave filter according to a fifth aspect of the present disclosure, in any one of the first to fourth aspects, when a width of a passband of the transmission filter is defined by a width from a −3 dB attenuation point on a low-frequency side to a −3 dB attenuation point on a high-frequency side in attenuation characteristics of the transmission filter, and a width of a passband of the reception filter is defined by a width from a −3 dB attenuation point on a low-frequency side to a −3 dB attenuation point on a high-frequency side in attenuation characteristics of the reception filter, a width of the passband of the transmission filter may be wider than a width of the passband of the reception filter by 4 MHz or more.

In an acoustic wave filter according to a sixth aspect of the present disclosure, in any one of the first to fifth aspects, the piezoelectric-body layer may contain Y-cut X-propagation LT having a cut angle of 40° or less as a material, the low-acoustic-velocity film may contain SiO₂ as a material, and the support substrate may contain Si as a material.

In an acoustic wave filter according to a seventh aspect of the present disclosure, in any one of the first to sixth aspects, the piezoelectric-body layer may contain Y-cut X-propagation LT having a cut angle of 25°±3° as a material, the low-acoustic-velocity film may contain SiO₂ as a material, and the support substrate may contain Si as a material.

In an acoustic wave filter according to an eighth aspect of the present disclosure, in any one of the first to seventh aspects, the transmission filter may include a series resonator as the acoustic wave element, and a peak frequency of power consumption in the series resonator on a high-frequency side with respect to the passband of the transmission filter may be equal to or higher than 1.035 times a center frequency of the passband of the transmission filter.

A communication apparatus according to a ninth aspect of the present disclosure may include the acoustic wave filter according to any one of the first to eighth aspects.

### Supplementary Note

The invention according to the present disclosure has been described above based on various drawings and examples. However, the invention according to the present disclosure is not limited to the embodiments described above. That is, the invention according to the present disclosure can be modified in various ways within the scope described in the present disclosure, and embodiments obtained by combining technical means disclosed in the different embodiments as appropriate are also included in the technical scope of the invention according to the present disclosure. In other words, it should be noted that a person skilled in the art can easily make various variations or modifications based on the present disclosure. It should also be noted that these variations or modifications are included in the scope of the present disclosure.

### Reference Signs

1 Acoustic Wave Element
1S Series resonators
1S-1T to 1S-4T Series resonators in transmission filter (series resonators belonging to first acoustic wave element group)
1S-1R to 1S-4R Series resonators in reception filter (series resonators belonging to second acoustic wave element group)
2 Piezoelectric-body layer
3 IDT electrode
5 Low-acoustic-velocity film
6 Support substrate
100 Acoustic wave filter
109T Transmission filter
111R Reception filter
151 Communication apparatus

1. An acoustic wave filter comprising:
a plurality of acoustic wave elements, wherein
each of the acoustic wave elements comprises
a piezoelectric-body layer,
an IDT electrode located on the piezoelectric-body layer,
a low-acoustic-velocity film having an acoustic velocity lower than the acoustic velocity of the piezoelectric-body layer, and
a support substrate having an acoustic velocity higher than the acoustic velocity of the piezoelectric-body layer,
when a wavelength of an acoustic wave excited by the IDT electrode is denoted by λ, a thickness of the piezoelectric-body layer is equal to or less than λ,
the acoustic wave filter comprises
a transmission filter comprising a first acoustic wave element group among the plurality of acoustic wave elements, and
a reception filter comprising a second acoustic wave element group different from the first acoustic wave element group among the plurality of acoustic wave elements,
a passband of the transmission filter is located on a higher frequency side than a passband of the reception filter, and
a width of the passband of the transmission filter is wider than a width of the passband of the reception filter.

2. An acoustic wave filter comprising:
a plurality of acoustic wave elements, wherein
each of the acoustic wave elements comprises
a piezoelectric-body layer,
an IDT electrode located on the piezoelectric-body layer,
a low-acoustic-velocity film having an acoustic velocity lower than the acoustic velocity of the piezoelectric-body layer, and
a support substrate having an acoustic velocity higher than the acoustic velocity of the piezoelectric-body layer,
when a wavelength of an acoustic wave excited by the IDT electrode is denoted by λ, a thickness of the piezoelectric-body layer is equal to or less than λ,
the acoustic wave filter comprises
a transmission filter comprising a first acoustic wave element group among the plurality of acoustic wave elements, and
a reception filter comprising a second acoustic wave element group different from the first acoustic wave element group among the plurality of acoustic wave elements,
a passband of the transmission filter is spaced apart from a passband of the reception filter by 50 MHz or more, and
a width of the passband of the transmission filter is wider than a width of the passband of the reception filter.

3. The acoustic wave filter according to claim 2, wherein the passband of the transmission filter is spaced apart from the passband of the reception filter by 300 MHz or more.

4. The acoustic wave filter according to claim 1, wherein
when a width of the passband of the transmission filter is defined by a width from a −3 dB attenuation point on a low-frequency side to a −3 dB attenuation point on a high-frequency side in attenuation characteristics of the transmission filter, and
a width of the passband of the reception filter is defined by a width from a −3 dB attenuation point on a low-frequency side to a −3 dB attenuation point on a high-frequency side in attenuation characteristics of the reception filter,
a width of the passband of the transmission filter is wider than a width of the passband of the reception filter by 2 MHz or more.

5. The acoustic wave filter according to claim 1, wherein
when a width of the passband of the transmission filter is defined by a width from a −3 dB attenuation point on a low-frequency side to a −3 dB attenuation point on a high-frequency side in attenuation characteristics of the transmission filter, and
a width of the passband of the reception filter is defined by a width from a −3 dB attenuation point on a low-frequency side to a −3 dB attenuation point on a high-frequency side in attenuation characteristics of the reception filter,
a width of the passband of the transmission filter is wider than a width of the passband of the reception filter by 4 MHz or more.

6. The acoustic wave filter according to claim 1, wherein the piezoelectric-body layer contains Y-cut X-propagation LT having a cut angle of 40° or less as a material,
the low-acoustic-velocity film contains SiO2 as a material, and the support substrate contains Si as a material.

7. The acoustic wave filter according to claim 1, wherein the piezoelectric-body layer contains Y-cut X-propagation LT having a cut angle of 25 ±3° as a material,
the low-acoustic-velocity film contains SiO2 as a material, and
the support substrate contains Si as a material.

8. The acoustic wave filter according to claim 1, wherein
the transmission filter comprises a series resonator as the acoustic wave element, and
a peak frequency of power consumption in the series resonator on a high-frequency side with respect to the passband of the transmission filter is equal to or higher than 1.035 times a center frequency of the passband of the transmission filter.

9. A communication apparatus comprising:
the acoustic wave filter according to claim 1.
